(19) United States
(12) Patent Application Publication
(10) Pub. No.: US 2026/0088833 A1
(43) Pub. Date: Mar. 26, 2026

(54) METHOD FOR PERFORMING PARITY BIT CALCULATION WITH AID OF CIRCUIT COMPLEXITY REDUCTION FOR PERFORMING ERROR CORRECTION, AND ASSOCIATED APPARATUS

(71) Applicant: Realtek Semiconductor Corp., HsinChu (TW)

(72) Inventor: Po-Wei Ho, HsinChu (TW)

(73) Assignee: Realtek Semiconductor Corp., HsinChu (TW)

(21) Appl. No.: 19/322,728

(22) Filed: Sep. 9, 2025

(30) Foreign Application Priority Data
Sep. 25, 2024 (TW) 113136258

(51) Int. Cl. H03M 13/29; H03M 13/11

(52) U.S. Cl. CPC H03M 13/2942; H03M 13/1174

(57) ABSTRACT

A method for performing parity bit calculation with aid of circuit complexity reduction for performing error correction and associated apparatus are provided. The method may include: in an error correction circuit adopting a predetermined error correction code, configuring a first set of exclusive OR (XOR) operation circuits among a plurality of XOR operation circuits corresponding to a predetermined codeword length, rather than all XOR operation circuits among the plurality of XOR operation circuits, for reducing circuit complexity of the error correction circuit, where the first set of XOR operation circuits may be a set of optimized XOR operation circuits implemented based on parity bit coverage reduction; and utilizing the first set of XOR operation circuits to perform the parity bit calculation, for performing error correction corresponding to a shorter codeword length, where a smaller XOR operation count and a shorter critical path length can be reached.

### BACKGROUND OF THE INVENTION

### 1. Field of the Invention

The present invention is related to circuit design, and particularly, to a method for performing parity bit calculation with aid of circuit complexity reduction for performing error correction, and associated apparatus such as an error correction circuit and a circuit module using the error correction circuit.

### 2. Description of the Prior Art

As the performance and reliability of integrated circuits (ICs) become increasingly important, it has been suggested in the related art to incorporate error correction codes (ECCs) to prevent transient faults caused by soft errors. For example, the ECC function of a static random-access memory (SRAM) in a central processing unit (CPU) can be implemented using a single-error-correction-double-error-detection (SECDED) Hamming code. Since the data path for Hamming code encoding/decoding may comprise a large number of exclusive OR (XOR) logic operation units such as XOR logic gates, the increase in data path length when adding ECC functionality can be a common issue.

### SUMMARY OF THE INVENTION

Therefore, one of the objectives of the present invention is to provide a method for performing parity bit calculation with aid of circuit complexity reduction for performing error correction, and associated apparatus such as an error correction circuit and a circuit module using the said error correction circuit, in order to address the problems in the related art.

At least one embodiment of the present invention provides a method for performing parity bit calculation with aid of circuit complexity reduction for performing error correction. The method may comprise: in an error correction circuit adopting a predetermined error correction code, configuring a first set of exclusive OR (XOR) operation circuits among a plurality of XOR operation circuits corresponding to a predetermined codeword length, rather than all XOR operation circuits among the plurality of XOR operation circuits, for reducing circuit complexity of the error correction circuit, wherein the first set of XOR operation circuits can be a set of optimized XOR operation circuits implemented based on parity bit coverage reduction; and utilizing the first set of XOR operation circuits to perform the parity bit calculation, for performing error correction corresponding to a shorter codeword length, wherein the shorter codeword length is less than the predetermined codeword length. For example, the first set of XOR operation circuits can be the set of optimized XOR operation circuits implemented based on parity bit coverage reduction, to allow that, regarding a first data bit processed by the first set of XOR operation circuits and a second data bit not processed by the first set of XOR operation circuits, first parity bit coverage of a set of parity bits with respect to the first data bit is smaller than second parity bit coverage of the set of parity bits with respect to the second data bit.

At least one embodiment of the present invention provides an error correction circuit implemented according to the method mentioned above, wherein the error correction circuit may comprise: multiple XOR operation modules, arranged to calculate multiple parity bits according to a set of data bits corresponding to the shorter codeword length, for performing error correction of the set of data bits, wherein any XOR operation module among the multiple XOR operation modules comprises a portion of XOR operation circuits among the first set of XOR operation circuits, arranged to calculate a parity bit among the multiple parity bits according to at least portion of data bits among the set of data bits.

At least one embodiment of the present invention provides a circuit module that uses the error correction circuit, wherein the circuit module comprises the error correction circuit, and the set of data bits represent data bits output or input by the circuit module.

One of the advantages of the present invention is that through proper design, the method of the present invention, the error correction circuit, and the circuit module using the error correction circuit can minimize the critical path length of the error correction circuit while minimizing the computational effort, and more particularly, balance the data path computation length of the parity bits and/or syndrome while minimizing the chip area required for the computations. Additionally, the method of the present invention, the error correction circuit, and the circuit module using the error correction circuit can address the issues in the related art with fewer side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a parity bit count and selective operation circuit removal control scheme of a method for performing parity bit calculation with aid of circuit complexity reduction for performing error correction according to an embodiment of the present invention.

FIG. 2 illustrates a complexity reduction and balancing control scheme of the method according to an embodiment of the present invention.

FIG. 3 is a diagram illustrating the error correction circuit involved in the parity bit count and selective operation circuit removal control scheme shown in FIG. 1 according to an embodiment of the present invention.

FIG. 4 is a diagram illustrating the error correction circuit involved in the complexity reduction and balancing control scheme shown in FIG. 2 according to an embodiment of the present invention.

FIG. 5 is a diagram illustrating the error correction circuit involved in the complexity reduction and balancing control scheme shown in FIG. 2 according to another embodiment of the present invention.

FIG. 6 illustrates, in sub-diagram (a) thereof, an XOR operation module involved in the method according to an embodiment of the present invention, and illustrates, in sub-diagram (b) thereof, the circuit architecture of the XOR operation module.

FIG. 7 illustrates some implementation details of the method according to an embodiment of the present invention.

FIG. 8 illustrates, in sub-diagram (a) thereof, the error correction circuit involved in the complexity reduction and balancing control scheme shown in FIG. 2 according to an embodiment of the present invention, and illustrates, in sub-diagrams (b) and (c) thereof, the circuit modules using the error correction circuit according to some embodiments of the present invention.

FIG. 9 illustrates a flowchart of the method according to an embodiment of the present invention.

### DETAILED DESCRIPTION

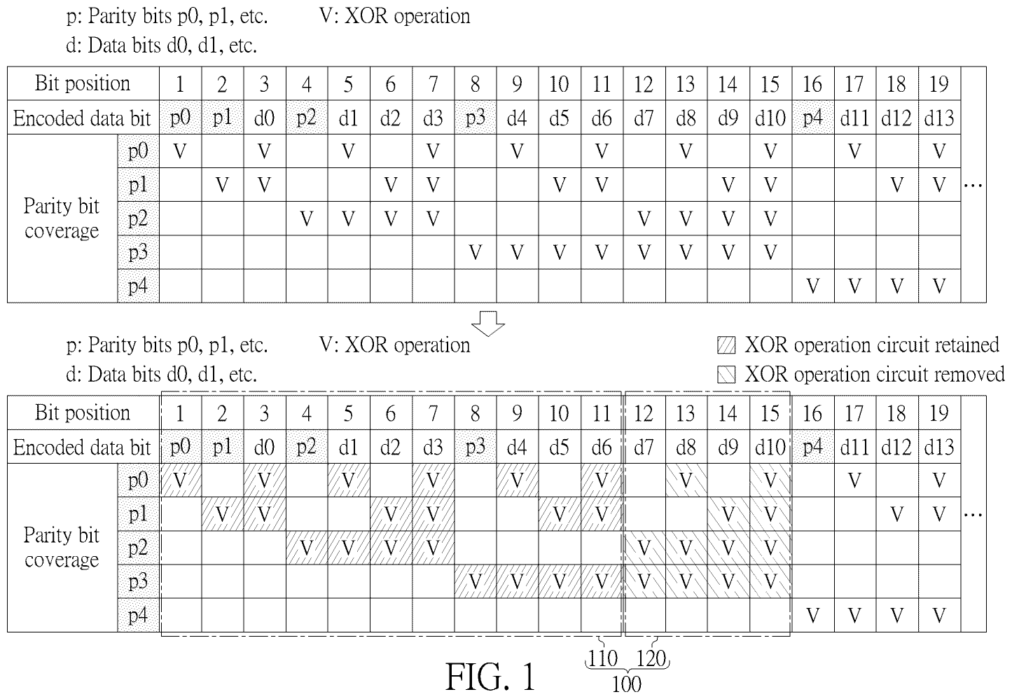

FIG. 1 illustrates a parity bit count and selective operation circuit removal control scheme of a method for performing parity bit calculation with aid of circuit complexity reduction for performing error correction according to an embodiment of the present invention. For an error correction circuit (such as error correction circuit 100) using a predetermined error correction code (e.g., Hamming code), parity bits {p} such as the parity bits {p0, p1, . . . } and data bits {d} such as the data bits {d0, d1, . . . } can be arranged as encoded data based on a predetermined parity bit rule that conforms to the predetermined error correction code, where the predetermined parity bit rule may comprise multiple sub-rules, such as a first sub-rule and a second sub-rule. As shown in the relationship between “Encoded data bit” and “Bit position” in the upper part of FIG. 1, the first sub-rule may comprise: the distribution of all data bits such as the data bits {d0, d1, . . . } and all parity bits such as the parity bits {p0, p1, . . . } in multiple encoded data bits {BIT(1), . . . , BIT(n)} (e.g., the bits {BIT(1), BIT(2), . . . } at the bit positions {1, 2, . . . }) of a first codeword CODEWORD1 having a predetermined codeword length n, with respect to the bit positions {1, 2, . . . } in the first codeword CODEWORD1. As shown in the relationship between “Parity bit coverage” and “Encoded data bit” in the upper part of FIG. 1, regarding the data protection of the aforementioned all data bits in the multiple encoded data bits {BIT(1), . . . , BIT(n)}, the second sub-rule may comprise: the parity bit coverage of the aforementioned all parity bits (e.g., the parity bits {p0, p1, . . . }) in the multiple encoded data bits {BIT(1), . . . , BIT(n)} with respect to the aforementioned all data bits (e.g., the data bits {d0, d1, . . . }) in the multiple encoded data bits {BIT(1), . . . , BIT(n)}.

The error correction circuit may operate according to the predetermined parity bit rule, and more particularly, perform encoding/decoding based on the first and the second sub-rules indicated by the mapping table shown in the upper part of FIG. 1. For example, in the case where the predetermined error correction code represents the Hamming code, the mapping table shown in the upper part of FIG. 1 can be regarded as the mapping table for its algorithm, and the associated implementation details for single-error correction (SEC) Hamming code may comprise:
(1) Number multiple bits {BIT} starting from 1: bits 1, 2, 3, 4, 5, 6, 7, etc., such as the bits {BIT(1), BIT(2), BIT(3), BIT(4), BIT(5), BIT(6), BIT(7), . . . };
(2) Write the respective number of the multiple bits {BIT} in binary form: 1, 10, 11, 100, 101, 110, 111, etc.;
(3) The bits {BIT} at all bit positions that are powers of 2, i.e., 1, 2, 4, 8, etc. (whose binary form is 1, 10, 100, 1000, etc., with a single 1), are parity bits {p};
(4) The bits {BIT} at all other bit positions (whose binary form contains two or more 1s) are data bits {d}; and
(5) Each data bit d is included (or protected) in a unique set of two or more parity bits {p}, determined by the binary form of its bit position, where:
(5.1) Bit BIT(1) (or parity bit p0) can cover or protect the bits at all bit positions whose binary form has the 0^{th} digit (e.g., the least significant bit (LSB)) equal to 1: bits BIT(1) (parity bit p0 itself), BIT(3), BIT(5), BIT(7), BIT(9), etc., at the bit positions 1, 11, 101, 111, 1001, etc.;
(5.2) Bit BIT(2) (or parity bit p1) can cover or protect the bits at all bit positions whose binary form has the 1^{st} digit (e.g., the second LSB, or the LSB after excluding the 0^{th} digit) equal to 1: bits BIT(2) (parity bit p1 itself), BIT(3), BIT(6), BIT(7), BIT(10), BIT(11), etc., at the bit positions 10, 11, 110, 111, 1010, 1011, etc.;
(5.3) Bit BIT(4) (or parity bit p2) can cover or protect the bits at all bit positions whose binary form has the 2^{nd} digit (e.g., the third LSB, or the LSB after excluding the 0^{th} and the 1^{st} digits) equal to 1: bits BIT(4) to BIT(7), BIT(12) to BIT(15), BIT(20) to BIT(23), etc., at the bit positions 100, 101, 110, 111, 1100, 1101, 1110, 1111, 10100, 10101, 10110, 10111, etc.;
(5.4) Bit BIT(8) (or parity bit p3) can cover or protect the bits at all bit positions whose binary form has the 3rd digit (e.g., the fourth LSB, or the LSB after excluding the 0^{th} to the 2^{nd} digits) equal to 1: bits BIT(8) to BIT(15), BIT(24) to BIT(31), BIT(40) to BIT(47), etc., at the bit positions 1000, 1001, 1010, 1011, 1100, 1101, 1110, 1111, 11000, 11001, 11010, 11011, 11100, 11101, 11110, 11111, 101000, 101001, 101010, 101011, 101100, 101101, 101110, 101111, etc.; and
(5.5) In general, each parity bit p can cover all bits where the bitwise AND of the parity position and the bit position is non-zero;
where the error correction circuit can use r parity bits {p0, p1, . . . , p(r−1)} to protect data (or the to-be-protected data) of length (n−r)=(2r−r−1) in the first codeword CODEWORD1 with the predetermined codeword length n (e.g., n=(2^{r}−1), where “r” may represent an integer greater than or equal to 2).

Additionally, the error correction circuit can utilize r parity bits {p0, p1, . . . , p(r−1)} to protect the data bits in the codewords {CODEWORD0} shorter than the predetermined codeword length n. For example, if the data byte to be encoded is 10011010, the data bits {d0, d1, d2, d3, d4, d5, d6, d7} in the data word 10011010 would be {1, 0, 0, 1, 1, 0, 1, 0}, and the error correction circuit can perform encoding according to the data bits {d0, d1, d2, d3, d4, d5, d6, d7} to generate the parity bits {p0, p1, p2, p3}.

As shown in the upper half of FIG. 1, “V” may represent an XOR operation, and the error correction circuit may comprise corresponding XOR operation circuits (e.g., XOR logic gates) for calculating the parity bits {p0, p1, . . . }. The multiple rows of XOR operations (marked as “V” for brevity) in the mapping table shown in the upper half of FIG. 1 can be performed by multiple rows of corresponding XOR operation circuits (or XOR logic gates). For any row of XOR operations among the multiple rows of XOR operations, it should be required that: the result of performing XOR operations on the encoding data bits corresponding to all XOR operations (or “V”) among the aforementioned any row of XOR operations must equal 0. Taking the first row of XOR operations as an example of the aforementioned any row of XOR operations:
p0\hat{ }d0\hat{ }d1\hat{ }d3 . . . =0, which means p0=d0\hat{ }d1\hat{ }d3 . . . ;
where the XOR operation is expressed with “\hat{ }” for better comprehension. Therefore, when calculating any parity bit p among the parity bits {p0, p1, . . . }, there is no need to perform an XOR operation on this parity bit p itself. Thus, in a row of corresponding XOR operation circuits (or XOR logic gates) corresponding to this parity bit p among the multiple rows of corresponding XOR operation circuits, there is no need to implement the XOR operation circuit (or XOR logic gates) corresponding to this XOR operation. Specifically, there is no need to perform the respective leftmost XOR operations of the multiple rows of XOR operations, and there is no need to implement the XOR operation circuits (or XOR logic gates) corresponding to these XOR operations.

For example, the error correction circuit can perform XOR operations on the data bits {d} at all bit positions whose binary form has the 0th digit (e.g., the LSB) equal to 1 to obtain the parity bit p0, where p0=d0\hat{ }d1\hat{ }d3 . . . ; the error correction circuit can perform XOR operations on the data bits {d} at all bit positions whose binary form has the 1^{st} digit (e.g., the second LSB, or the LSB after excluding the 0^{th} digit) equal to 1 to obtain the parity bit p1, where p1=d0\hat{ }d2\hat{ }d3 . . . ; the error correction circuit can perform XOR operations on the data bits {d} at all bit positions whose binary form has the 2^{nd} digit (e.g., the third LSB, or the LSB after excluding the 0^{th} to the 1^{st} digits) equal to 1 to obtain the parity bit p2, where p2=d1\hat{ }d2\hat{ }d3 . . . ; the error correction circuit can perform XOR operations on the data bits {d} at all bit positions whose binary form has the 3^{rd} digit (e.g., the fourth LSB, or the LSB after excluding the 0^{th} to the 2^{nd} digits) equal to 1 to obtain the parity bit p3, where p3=d4\hat{ }d5\hat{ }d6 . . . ; and on the rest can be deduced by analogy. Based on the first sub-rule, the parity bits {p} can be placed in positions corresponding to powers of 2, with the bit positions of the bits {BIT} being encoded starting from 1, and the data bits {d} to be encoded can be sequentially placed in the remaining positions. When encoding data having a data length Data_Length is needed, at least r parity bits {p}, such as the parity bits {p0, p1, . . . , p(r−1)}, are required, and for controlling the parity bit count r, r must satisfy the following inequality:

$$\begin{matrix}( 2 r - r - 1 ) \geq Data\_Length ; or \\ ( n - r ) \geq Data\_Length ;\end{matrix}$$

where n=(2^{r}−1). For example, when r=4, the error correction circuit can perform XOR operations on the data bits {d} at the bit positions whose binary form has the [0^{th}, 1^{st}, 2^{nd}, 3^{rd}] digit equal to 1 to generate the corresponding parity bits [p0, p1, p2, p3], for corresponding to 24 data bits, but the bits {BIT(1), BIT(2), BIT(4), BIT(8)} at the bit positions as powers of 2 are parity bits {p0, p1, p2, p3} and there is no encoded data bit corresponding to the bit position 0, so the maximum of the data length Data_Length can be (24−4−1)=11.

Based on the parity bit count and selective operation circuit removal control scheme, the error correction circuit, such as the error correction circuit 100, can be configured to comprise a first set of XOR operation circuits 110 among a plurality of XOR operation circuits corresponding to the predetermined codeword length n (e.g., n=(2^{r}−1)), rather than all XOR operation circuits (e.g., the first set of XOR operation circuits 110 and a second set of XOR operation circuits 120 differing from the first set of XOR operation circuits 110, assuming Data_Length=7) among the plurality XOR operation circuits, for reducing the circuit complexity of the error correction circuit 100, and can utilize the first set of XOR operation circuits 110 to perform the parity bit calculation, for performing error correction of the codewords {CODEWORD0} shorter than the predetermined codeword length n, wherein, when Data_Length=7, the first set of XOR operation circuits 110 can be illustrated as corresponding to the bit positions {1, 2, . . . , 11} (or the encoded data bits thereof reaching the data bit d6). In some examples, the respective sizes of the first set of XOR operation circuits 110 and the second set of XOR operation circuits 120 within the error correction circuit 100 may vary with changes in the data length Data_Length. Specifically, when Data_Length=5, the first set of XOR operation circuits 110 can be illustrated as corresponding to the bit positions {1, 2, . . . , 9} (or the encoded data bits thereof reaching the data bit d4), and the second set of XOR operation circuits 120 can be illustrated as corresponding to the remaining bit positions {10, 11, . . . , 15}.

Taking r=4 as an example for better comprehension, in the error correction circuit corresponding to the mapping table shown in the upper half of FIG. 1, all XOR operation circuits among the plurality of XOR operation circuits may comprise the first set of XOR operation circuits 110 and a second set of XOR operation circuits 120, which is outside the first set of XOR operation circuits 110. In comparison with this, in the error correction circuit 100 corresponding to the mapping table shown in the lower half of FIG. 1, when r=4 and Data_Length=7, the first set of XOR operation circuits 110 can be retained, while the second set of XOR operation circuits 120 can be removed. According to some embodiments, the predetermined codeword length n, the parity bit count r, and/or the data length Data_Length may vary.

The associated implementation details regarding the selective operation circuit removal can be further described as follows. According to some embodiments, when r=4, the error correction circuit can perform encoding for data up to 11 bits, meaning that the error correction circuit can also perform encoding for data of only 7 bits. When encoding 7-bit data with just 4 parity bits {p}, the input terminals of the error correction circuit (e.g., encoding circuit) for the data bits {do, . . . , d6} can be configured to receive the data bits {d0, . . . , d6}, and the input terminals of the error correction circuit for the data bits {d7, d8, d9, d10} can be configured to receive fixed values, such as 0, to represent “don't care.” In this case, when calculating the parity bits {p0, . . . , p3}, since performing an XOR operation with 0 results in the original value, the input signals corresponding to the data bits {d7, d8, d9, d10} (that carry the fixed value such as 0) will not affect the entire error correction circuit (e.g., the encoding circuit). As a result, the complexity of the error correction circuit can be simplified by directly removing the associated circuits of the input signals corresponding to the data bits {d7, d8, d9, d10}, thereby implementing a 7-bit Hamming code encoding/decoding circuit. For brevity, similar descriptions for these embodiments are not repeated in detail here.

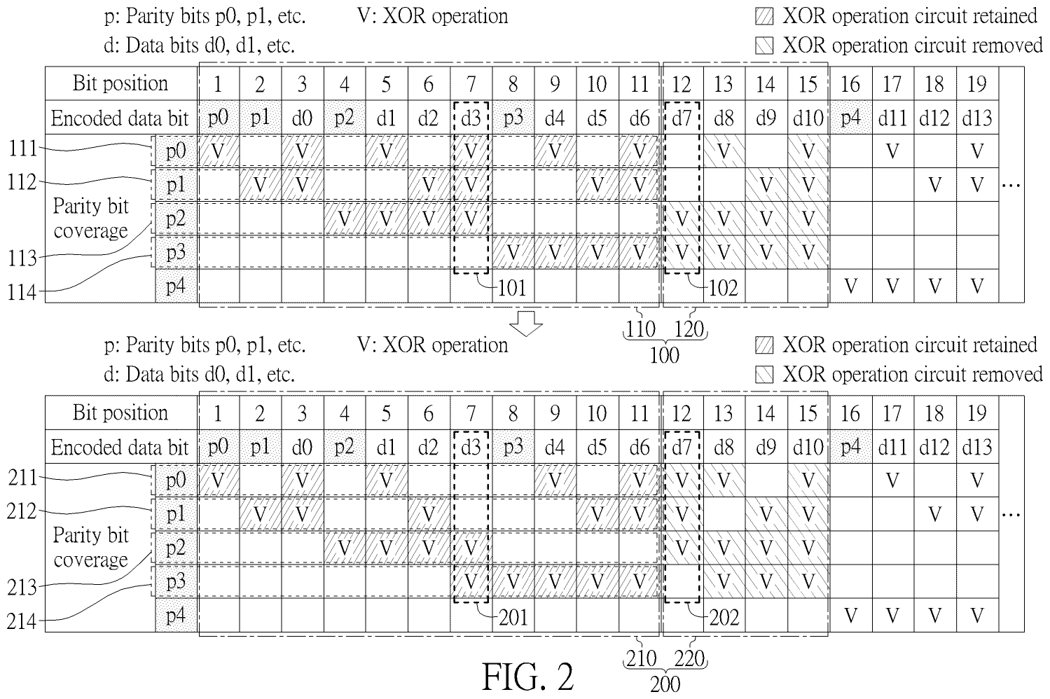

FIG. 2 illustrates a complexity reduction and balancing control scheme of the method according to an embodiment of the present invention. Taking r=4 as an example, in the error correction circuit 100 implemented based on the parity bit count and selective operation circuit removal control scheme shown in FIG. 1, the multiple rows of corresponding XOR operation circuits mentioned above can be implemented as multiple XOR operation modules such as four XOR operation modules 111, 112, 113, and 114, and the parity bit coverage 101 of the parity bits {p0, . . . , p3} with respect to the data bit d3 is greater than the parity bit coverage 102 of the parity bits {p0, . . . , p3} with respect to the data bit d7, and more particularly, the XOR operation count (or XOR operation circuit count) of the associated XOR operations (or XOR operation circuits) of the parity bit coverage 101 is greater than the XOR operation count (or XOR operation circuit count) of the associated XOR operations (or XOR operation circuits) of the parity bit coverage 102. In comparison with this, in the error correction circuit 200 implemented based on the complexity reduction and balancing control scheme, the multiple rows of corresponding XOR operation circuits mentioned above can be implemented as multiple XOR operation modules such as four XOR operation modules 211, 212, 213, and 214, and the first set of XOR operation circuits 210 can be a set of optimized XOR operation circuits implemented based on parity bit coverage reduction, to allow that, regarding a first data bit (such as the data bit d3) processed by the first set of XOR operation circuits 210 and a second data bit (such as data bit d7) not processed by the first set of XOR operation circuits 210, the first parity bit coverage 201 of the parity bits {p0, . . . , p3} with respect to the data bit d3 is smaller than the second parity bit coverage 202 of the parity bits {p0, . . . , p3} with respect to the data bit d7, and more particularly, the XOR operation count (or XOR operation circuit count) of the associated XOR operations (or XOR operation circuits) of the parity bit coverage 201 is smaller than the XOR operation count (or XOR operation circuit count) of the associated XOR operations (or XOR operation circuits) of the parity bit coverage 202, making the circuit complexity of the error correction circuit 200 be simplified/reduced compared to the circuit complexity of the error correction circuit 100.

By utilizing redundant removable XOR operation circuits, the error correction circuit (or the internal encoding logic circuit thereof) using the predetermined error correction code (e.g., Hamming code) can be redesigned to transform from the error correction circuit 100 into the error correction circuit 200. When the internal encoding logic circuit (e.g., the associated XOR operation circuit of the parity bit coverage 101) for one data bit d among the data bits {d0, . . . , d6} is more complicated than the removable internal encoding logic circuit (e.g., the associated XOR operation circuit of the parity bit coverage 102) for one data bit d among the data bits {d7, . . . , d10}, the method can prioritize the removal/reduction of the more complicated circuits by rearranging, ultimately achieving a reduction in chip area, while configuring balanced local parity operation circuits (e.g., the XOR operation modules 211, 212, 213, and 214), for example, by balancing the respective data processing paths of the local parity operation circuits respectively used for generating the parity bits {p0, . . . , p3} to make the computation load be evenly distributed, and minimizing the longest computation/operation path length (e.g., the length of the longest data processing path among these paths) to reduce the chances of these data processing paths becoming critical paths.

As shown in the upper half of FIG. 2, the XOR operations for the parity bit coverage 101 of the data bit d3 includes three XOR operations for generating the parity bits {p0, p1, p2}, while the removable XOR operation for the parity bit coverage 102 of the data bit d7 includes two XOR operations for generating the parity bits {p2, p3}. As shown in the lower half of FIG. 2, after the internal circuits are redesigned/rearranged, the data bit d3 can be used for generating the parity bits {p2, p3}, while the data bit d7 can be used for generating the parity bits {p0, p1, p2}. Since the corresponding XOR operation circuits for the parity bit coverage 202 of the data bit d7 can ultimately be removed/reduced, in comparison with the XOR path lengths {5, 5, 3, 3} (measured in units of XOR logic gates, taking XOR gate chains as examples for better comprehension) of the XOR operation modules 111, 112, 113, and 114, the XOR path lengths {4, 4, 3, 4} of the XOR operation modules 211, 212, 213, and 214 may have become more balanced, where the XOR operation modules 211 and 212 for generating the parity bits p0 and p1 can save one bit of operation to make the XOR path length change from 5 to 4, the XOR operation module 213 for generating the parity bit p2 can maintain the same XOR path length such as 3, and the XOR operation module 214 for generating the parity bit p3 can increase by one bit of operation to make the XOR path length change from 3 to 4. Therefore, the corresponding chip area for all XOR operations/XOR operation circuits required for the parity bits {p0, p1, p2, p3} decreases (from (5+5+3+3) to (4+4+3+4)), and the XOR operation path length of the longest XOR operation module among the respective XOR operation modules of all parity bits {p0, p1, p2, p3} is reduced (from 5 to 4). For brevity, similar descriptions for this embodiment are not repeated in detail here.

According to some embodiments, in the complexity reduction and balancing control scheme, the predetermined codeword length n, the parity bit count r, and/or the data length Data_Length may vary. For brevity, similar descriptions for these embodiments are not repeated in detail here.

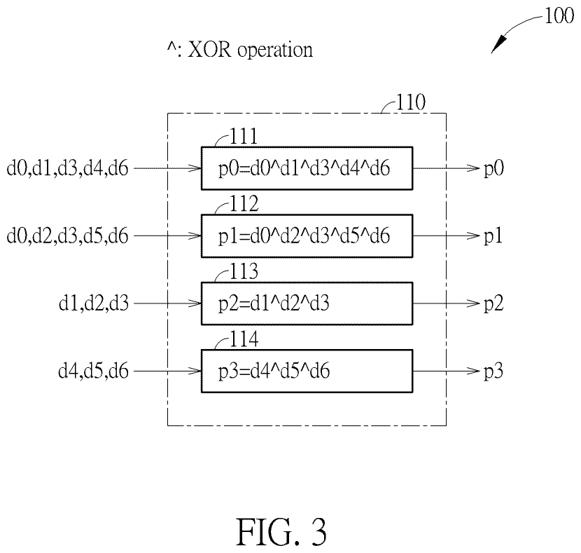

FIG. 3 is a diagram illustrating the error correction circuit 100 involved in the parity bit count and selective operation circuit removal control scheme shown in FIG. 1 according to an embodiment of the present invention. The first set of XOR operation circuits 110 in the error correction circuit 100 corresponding to the mapping table shown in the lower half of FIG. 1 can be configured based on the data length Data_Length (e.g., the number of data bits required for the codeword CODEWORD0), in order to implement the error correction circuit 100 as shown in FIG. 3 in a situation where r=4 and Data_Length=7, for performing encoding/decoding regarding the 7 data bits {d0, . . . , d6}. Specifically, the r XOR operation modules for computing the aforementioned r parity bits {p0, p1, . . . , p(r−1)} may comprise XOR operation modules 111, 112, 113, and 114 for calculating the parity bits {p0, p1, p2, p3} as follows:

$$\begin{matrix}p 0 = d 0 \hat{} d 1 \hat{} d 3 \hat{} d 4 \hat{} d 6 ; \\ p 1 = d 0 \hat{} d 2 \hat{} d 3 \hat{} d 5 \hat{} d 6 ; \\ p 2 = d 1 \hat{} d 2 \hat{} d 3 ; and \\ p 3 = d 4 \hat{} d 5 \hat{} d 6.\end{matrix}$$

According to some embodiments, the predetermined codeword length n, the parity bit count r, and/or the data length Data_Length may vary, and the aforementioned r XOR operation modules may vary correspondingly.

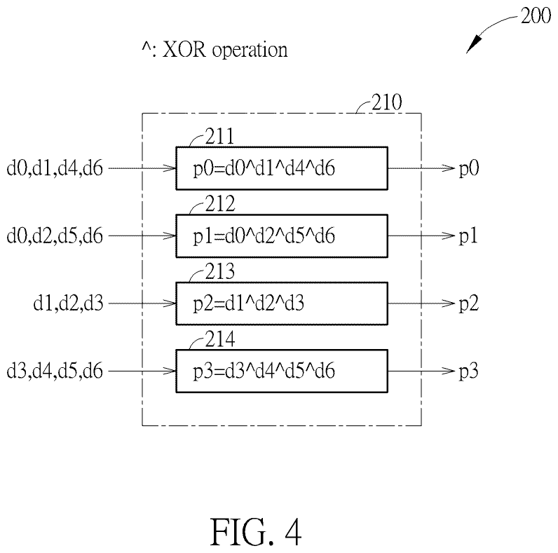

FIG. 4 is a diagram illustrating the error correction circuit 200 involved in the complexity reduction and balancing control scheme shown in FIG. 2 according to an embodiment of the present invention. The first set of XOR operation circuits 210 in the error correction circuit 200 corresponding to the mapping table shown in the lower half of FIG. 2 can be configured based on the data length Data_Length (e.g., the number of data bits required for the codeword CODEWORD0), in order to implement the error correction circuit 200 as shown in FIG. 4 in a situation where r=4 and Data_Length=7, for performing encoding/decoding regarding the 7 data bits {d0, . . . , d6}. Specifically, the r XOR operation modules for computing the aforementioned r parity bits {p0, p1, . . . , p(r−1)} may comprise XOR operation modules 211, 212, 213, and 214 for calculating the parity bits {p0, p1, p2, p3} as follows:

$$\begin{matrix}p 0 = d 0 \hat{} d 1 \hat{} d 4 \hat{} d 6 ; \\ p 1 = d 0 \hat{} d 2 \hat{} d 5 \hat{} d 6 ; \\ p 2 = d 1 \hat{} d 2 \hat{} d 3 ; and \\ p 3 = d 3 \hat{} d 4 \hat{} d 5 \hat{} d 6.\end{matrix}$$

According to some embodiments, the predetermined codeword length n, the parity bit count r, and/or the data length Data_Length may vary, and the aforementioned r XOR operation modules may vary correspondingly.

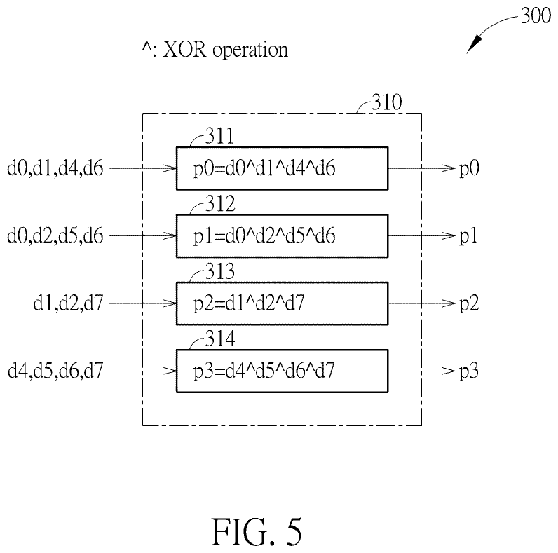

FIG. 5 is a diagram illustrating the error correction circuit 300 involved in the complexity reduction and balancing control scheme shown in FIG. 2 according to another embodiment of the present invention. The mapping table shown in the upper half of FIG. 2 can be modified into a data-bit-exchange-based mapping table, such as a mapping table where data bits d3 and d7 are exchanged with each other, which means that in the new mapping table, the data bits d3 and d7 in the encoded data bits are replaced by the data bits d7 and d3, respectively. In response to the change in the architecture, the first set of XOR operation circuits 110, the XOR operation modules 211, 212, 213, and 214, etc., can be replaced by the first set of XOR operation circuits 310, the XOR operation modules 311, 312, 313, and 314, etc., respectively. The first set of XOR operation circuits 310 in the error correction circuit 300 corresponding to the data-bit-exchange-based mapping table can be configured based on the data length Data_Length (e.g., the number of data bits required for the codeword CODEWORD0), in order to implement the error correction circuit 300 as shown in FIG. 5 in a situation where r=4 and Data_Length=7, for performing encoding/decoding regarding the 7 data bits {d0, . . . , d6}. Specifically, the r XOR operation modules for computing the aforementioned r parity bits {p0, p1, . . . , p(r−1)} may comprise XOR operation modules 311, 312, 313, and 314 for calculating the parity bits {p0, p1, p2, p3} as follows:

$$\begin{matrix}p 0 = d 0 \hat{} d 1 \hat{} d 4 \hat{} d 6 ; \\ p 1 = d 0 \hat{} d 2 \hat{} d 5 \hat{} d 6 ; \\ p 2 = d 1 \hat{} d 2 \hat{} d 7 ; and \\ p 3 = d 4 \hat{} d 5 \hat{} d 6 \hat{} d 7.\end{matrix}$$

According to some embodiments, the predetermined codeword length n, the parity bit count r, and/or the data length Data_Length may vary, and the aforementioned r XOR operation modules may vary correspondingly.

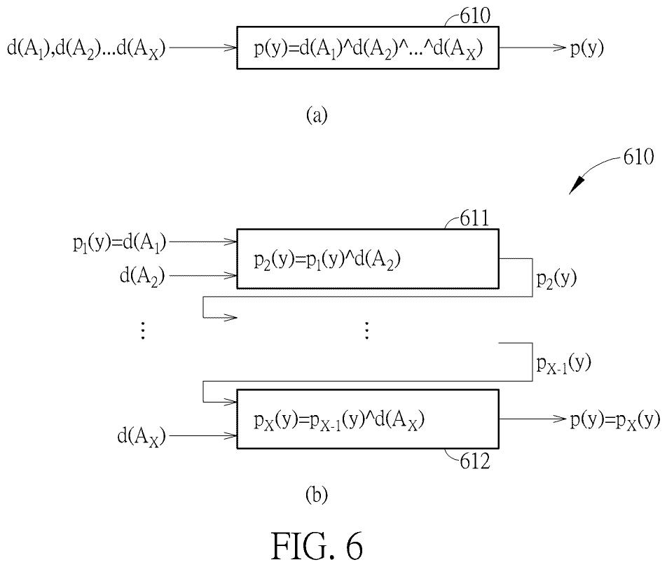

FIG. 6 illustrates, in sub-diagram (a) thereof, an XOR operation module 610 involved in the method according to an embodiment of the present invention, and illustrates, in sub-diagram (b) thereof, the circuit architecture of the XOR operation module 610. Assuming that “X” represents a positive integer greater than one, the XOR operation module 610 may comprise (X−1) XOR operation circuits such as XOR operation circuits 611, . . . and 612, and each XOR operation circuit among these XOR operation circuits can be implemented using an XOR logic gate. Moreover, any XOR operation module among the r XOR operation modules (e.g., the XOR operation modules 111, 112, 113, 114 shown in FIG. 3, the XOR operation modules 211, 212, 213, 214 shown in FIG. 4, or the XOR operation modules 311, 312, 313, 314 shown in FIG. 5) for calculating the aforementioned r parity bits {p0, p1, . . . , p(r−1)} can be implemented with a similar or identical circuit architecture as the XOR operation module 610, for computing the corresponding parity bit p(y) along with the associated parity bits {p₂(y), . . . , p_{X}(y)} according to the received data bits thereof such as the X data bits {d(A₁), d(A₂), . . . , d(A_{X})} as follows:

$$\begin{matrix}p ( y ) = d ( {A}_{1} ) \hat{} d ( {A}_{2} ) \hat{} … \hat{} d ( {A}_{X} ) ; \\ {p}_{2} ( y ) = {p}_{1} ( y ) \hat{} d ( {A}_{2} ) ; \\ … ; and \\ {p}_{X} ( y ) = {p}_{X - 1} ( y ) \hat{} d ( {A}_{X} ) ;\end{matrix}$$

According to some embodiments, the circuit architecture of the XOR operation module 610 and/or the order/sequence of the X data bits {d(A₁), d(A₂), . . . , d(A_{X})} may vary, and the aforementioned r XOR operation modules may vary correspondingly.

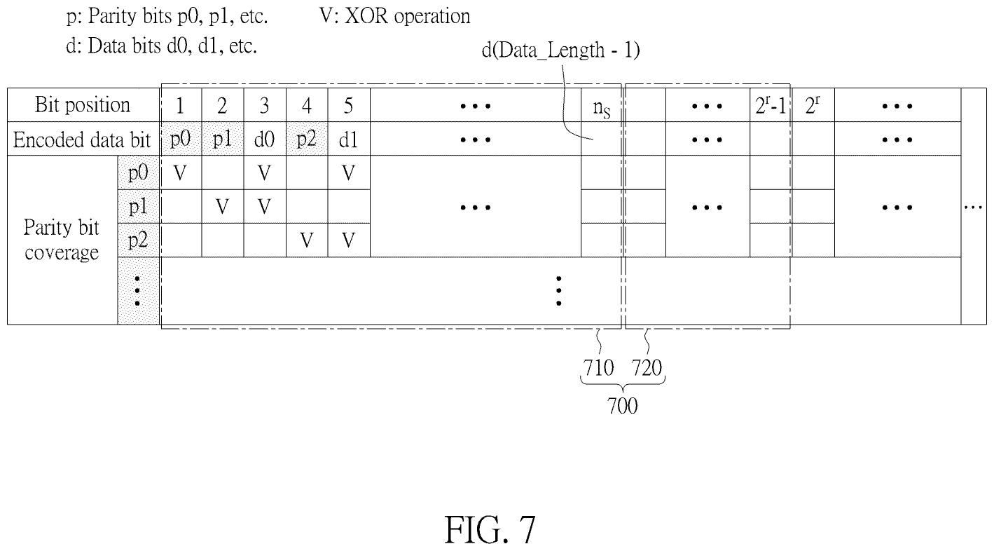

FIG. 7 illustrates some implementation details of the method according to an embodiment of the present invention. For example, the associated operations of the method may comprise:
(1) In the error correction circuit (e.g., the error correction circuit 700) that uses the predetermined error correction code (e.g., Hamming code), configuring a first set of XOR operation circuits 710 among the plurality of XOR operation circuits corresponding to the predetermined codeword length n (e.g., n=(2^{r}−1)), rather than all XOR operation circuits (e.g., the first set of XOR operation circuits 710 and a second set of XOR operation circuits 720 diffing from the first set of XOR operation circuits 710) among the plurality of XOR operation circuits, for reducing the circuit complexity of the error correction circuit 700; and
(2) Utilizing the first set of XOR operation circuits 710 to perform the parity bit calculation, for performing error correction corresponding to a shorter codeword length n_{S} (e.g., the length of the codewords {CODEWORD0}), where the shorter codeword length n_{S} is less than the predetermined codeword length n, in particular, n_{S} is a positive integer and n_{S}<n=(2^{r}−1). where in the mapping table shown in FIG. 7, the distribution of the XOR operations involved in the first set of XOR operation circuits 710 with respect to the bit position/the encoded data bits (or the rightmost boundary thereof) may reach the data bit d (Data_Length−1) among the encoded data bits, and some content may be omitted for brevity. For better comprehension, when r=4 and Data_Length=7, the error correction circuit 700, the first set of XOR operation circuits 710, and the second set of XOR operation circuits 720 may respectively represent the error correction circuit 100, the first set of XOR operation circuits 110, and the second set of XOR operation circuits 120 shown in FIG. 1 or FIG. 2, or the error correction circuit 200, the first set of XOR operation circuits 210, and the second set of XOR operation circuits 220 shown in FIG. 2. More particularly, when r=4 and Data_Length=7, the error correction circuit 700, the first set of XOR operation circuits 710, etc. may respectively represent the error correction circuit 100, the first set of XOR operation circuits 110, etc. shown in FIG. 3, or the error correction circuit 200, the first set of XOR operation circuits 210, etc. shown in FIG. 4, or the error correction circuit 300, the first set of XOR operation circuits 310, etc. shown in FIG. 5. In some examples, the predetermined codeword length n, the parity bit count r, and/or the data length Data_Length may vary, and the error correction circuit 700, the first set of XOR operation circuits 710 and the second set of XOR operation circuits 720 may vary correspondingly. For brevity, similar descriptions for this embodiment are not repeated in detail here.

According to some embodiments, the error correction circuit 700 can generate the aforementioned r parity bits {p0, p1, . . . , p(r−1)} for protecting a set of data bits corresponding to the shorter codeword length n_{S}. For example: when r=3, the parity bits {p0, p1, . . . , p(r−1)} may comprise the parity bits {p0, p1, p2}; when r=4, the parity bits {p0, p1, . . . , p(r−1)} may comprise the parity bits {p0, p1, p2, p3}; when r=5, the parity bits {p0, p1, . . . , p(r−1)} may comprise the parity bits {p0, p1, p2, p3, p4}; and the rest can be deduced by analogy. If the potential cost increase is disregarded, it is feasible to implement additional parity bits to extend the range of the second set of XOR operation circuits 720 with respect to the bit position or the encoded data bit, where the opportunity of further simplifying, based on the complexity reduction and balancing control scheme, the first set of XOR operation circuits 710 to reduce the circuit complexity (or reduce the computation/operation length for the parity bits {p}) may increase. For instance, when the configuration changes from an original configuration such as (r=4, Data_Length=7) to a new configuration such as (r=5, Data_Length=7) for performing encoding on 7 data bits {d0, . . . , d6} with 5 parity bits {p0, p1, p2, p3, p4}), the second set of XOR operation circuits 720 that is removable may correspond to the unused data bits {d7, . . . , d25} and provide more combinations for rearranging. In such a case, it is suggested to prioritize selecting the data bit d that participates in the generation of the parity bit p4 but are involved in fewer computations for the other parity bits {p}, for increasing the opportunity to share the corresponding chip area associated with the computations of the parity bits {p0, . . . , p3} with that of the parity bit p4 and further reducing the longest computation length. For brevity, similar descriptions for these embodiments are not repeated in detail here.

According to some embodiments, given that the predetermined codeword length n is equal to (2^{r}−1) and the maximum data length k is equal to (2^{r}−r−1), the data length Data_Length may be less than or equal to the maximum data length k. If Data_Length=k, the bit rate R may be written as R=(k/n)=(1−(r/(2^{r}−1))); otherwise, in a situation where Data_Length<k, the bit rate R may be written as R=(Data_Length/(Data_Length+r)). For brevity, similar descriptions for these embodiments are not repeated in detail here.

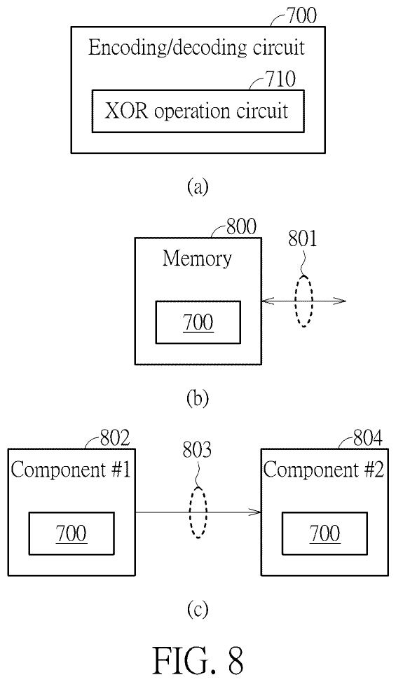

FIG. 8 illustrates, in sub-diagram (a) thereof, the error correction circuit 700 involved in the complexity reduction and balancing control scheme shown in FIG. 2 according to an embodiment of the present invention, and illustrates, in sub-diagrams (b) and (c) thereof, the circuit modules 800, 802, and 804 using the error correction circuit 700 according to some embodiments of the present invention, where the error correction circuit 700 may be implemented as an encoding/decoding circuit (labeled as “Encoding/Decoding Circuit” for brevity), and the circuit modules 800, 802, and 804 may be implemented as a memory, a transmission end component, and a receiving end component (labeled as “Memory”, “Component #1”, and “Component #2” for brevity), respectively. Any circuit module using the error correction circuit 700, such as the circuit modules 800, 802, and 804, may comprise the error correction circuit 700, where multiple XOR operation modules within the error correction circuit 700 may calculate multiple parity bits based on the set of data bits corresponding to the shorter codeword length n_{S}, for performing error correction of the set of data bits. Additionally, the set of data bits may represent the data bits output or input by the aforementioned any circuit module. For example, the set of data bits may represent the data bits output or input by the circuit module 800 via the bus 801, or the data bits output by the circuit module 802 via the bus 803, or the data bits input by the circuit module 804 via the bus 803. For brevity, similar descriptions for this embodiment are not repeated in detail here.

According to some other embodiments, the error correction circuit 700, the circuit modules 800, 802, and 804, and/or the buses 801 and 803 may vary. For brevity, similar descriptions for these embodiments are not repeated in detail here.

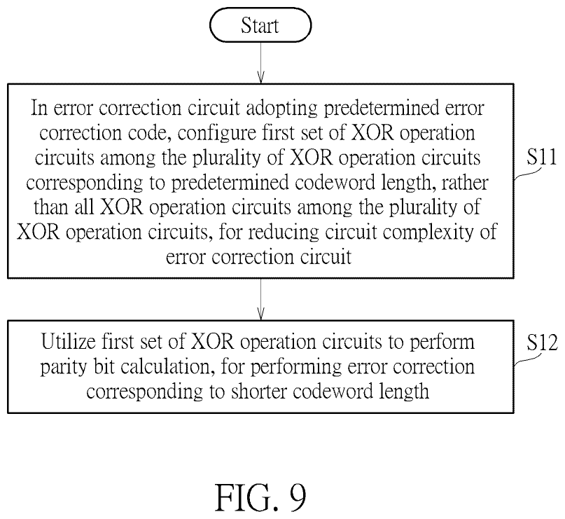

FIG. 9 illustrates a flowchart of the method according to an embodiment of the present invention, where the error correction circuit 700 may be implemented based on the method, and may comprise the first set of XOR operation circuits 710.

In Step S11, in the error correction circuit 700 adopting/using the predetermined error correction code (e.g., Hamming code), configure a first set of XOR operation circuits 710 among the plurality of XOR operation circuits corresponding to the predetermined codeword length n (e.g., n=(2^{r}−1)), rather than all XOR operation circuits (e.g., the first set of XOR operation circuits 710 and the second set of XOR operation circuits 720 diffing from the first set of XOR operation circuits 710) among the plurality of XOR operation circuits, for reducing the circuit complexity of the error correction circuit 700, where the plurality of XOR operation circuits may represent XOR operation circuits that conform to the aforementioned predetermined parity bit rules (or the sub-rules thereof such as the first and the second sub-rules). The first set of XOR operation circuits 710 may comprise or may be divided into multiple XOR operation modules, such as the r XOR operation modules corresponding to the aforementioned r parity bits {p0, p1, . . . , p(r−1)}. For example, when r=4 and Data_Length=7, the r XOR operation modules may represent the XOR operation modules 111, 112, 113, and 114 shown in FIG. 3, or the XOR operation modules 211, 212, 213, and 214 shown in FIG. 4, or the XOR operation modules 311, 312, 313, and 314 shown in FIG. 5. In particular, the first set of XOR operation circuits 710 may be a set of optimized XOR operation circuits implemented based on parity bit coverage reduction, where when r=4 and Data_Length=7, the r XOR operation modules may represent the XOR operation modules 211, 212, 213, and 214 shown in FIG. 4.

In Step S12, utilize the first set of XOR operation circuits 710 to perform the parity bit calculation, for performing the error correction corresponding to the shorter codeword length n_{S}. Regarding the first set of XOR operation circuits 710, the multiple XOR operation modules such as the aforementioned r XOR operation modules may calculate multiple parity bits {p} according to a set of data bits {d} corresponding to the shorter codeword length n_{S}, for performing the error correction of the set of data bits {d}, where any XOR operation module among the multiple XOR operation modules may comprise a portion of XOR operation circuits among the first set of XOR operation circuits 710, for calculating a parity bit p among the multiple parity bits {p} according to at least one portion of data bits {d} among the set of data bits {d}.

The plurality of XOR operation circuits may represent a plurality of XOR logic gates. According to some embodiments, if r=4, the difference between the respective lengths of any two XOR operation modules among the multiple XOR operation modules (e.g., the XOR operation modules 211, 212, 213, and 214 shown in FIG. 4, or the XOR operation modules 311, 312, 313, and 314 shown in FIG. 5) may be less than or equal to one XOR logic gate (or the length thereof), in order to achieve or approach a balanced data path length; otherwise, the difference between the respective lengths of the aforementioned any two XOR operation modules is not necessarily limited to being less than or equal to one XOR logic gate (or the length thereof). According to some other embodiments, the method may adopt/use various selection ways to achieve balance as much as possible, without restricting the difference between the respective lengths of the aforementioned any two XOR operation modules to being exactly equal to one XOR logic gate (or the length thereof) or any specific number of XOR logic gates (or the length thereof).

Based on the method, the error correction circuit 700 and the circuit module (e.g., the circuit modules 800, 802, and 804) that uses the error correction circuit 700 can achieve minimization of the critical path length of the error correction circuit 700 while minimizing the computational effort, and more particularly, balance the data path computation length of the parity bits {p0, p1, . . . , p(r−1)} while minimizing the chip area required for the computations. For brevity, similar descriptions for this embodiment are not repeated in detail here.

For better comprehension, the method can be described with the working flow shown in FIG. 9. According to some embodiments, one or more steps may be added, removed, or modified in the working flow shown in FIG. 9. For example, at least one XOR operation circuit (e.g., the associated XOR operation circuits of the parity bit coverage 201) among the first set of XOR operation circuits 710 (e.g., the first set of XOR operation circuits 210) does not conform to the predetermined parity bit rule, as if having been replaced or swapped with at least one corresponding XOR operation circuit (e.g., the associated XOR operation circuits of the parity bit coverage 202) among the second set of XOR operation circuits 720 other than the first set of XOR operation circuits 710. For brevity, similar descriptions for these embodiments are not repeated in detail here.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for performing parity bit calculation with aid of circuit complexity reduction for performing error correction, the method comprising:
in an error correction circuit adopting a predetermined error correction code, configuring a first set of exclusive OR (XOR) operation circuits among a plurality of XOR operation circuits corresponding to a predetermined codeword length, rather than all XOR operation circuits among the plurality of XOR operation circuits, for reducing circuit complexity of the error correction circuit, wherein the first set of XOR operation circuits is a set of optimized XOR operation circuits implemented based on parity bit coverage reduction; and
utilizing the first set of XOR operation circuits to perform the parity bit calculation, for performing error correction corresponding to a shorter codeword length, wherein the shorter codeword length is less than the predetermined codeword length.

2. The method of claim 1, wherein the predetermined error correction code represents Hamming code.

3. The method of claim 1, wherein the plurality of XOR operation circuits represent XOR operation circuits conforming to a predetermined parity bit rule of the predetermined error correction code.

4. The method of claim 3, wherein a first sub-rule in the predetermined parity bit rule comprises a distribution of all data bits and all parity bits in multiple encoded data bits of a first codeword having the predetermined codeword length, with respect to bit positions in the first codeword.

5. The method of claim 4, wherein regarding data protection of said all data bits in the multiple encoded data bits, a second sub-rule in the predetermined parity bit rule comprises parity bit coverage of said all parity bits in the multiple encoded data bits with respect to said all data bits in the multiple encoded data bits.

6. The method of claim 3, wherein at least one XOR operation circuit in the first set of XOR operation circuits does not conform to the predetermined parity bit rule, as if having been replaced or swapped with at least one corresponding XOR operation circuit among a second set of XOR operation circuits other than the first set of XOR operation circuits.

7. The method of claim 1, wherein the predetermined codeword length is equal to (2^{r}−1), wherein r is an integer greater than or equal to two.

8. The method of claim 1, wherein the plurality of XOR operation circuits represent a plurality of XOR logic gates, and the error correction circuit comprises multiple XOR operation modules, wherein any XOR operation module among the multiple XOR operation modules comprises a portion of XOR operation circuits among the first set of XOR operation circuits.

9. An error correction circuit implemented according to the method of claim 1, wherein the error correction circuit comprises:
multiple XOR operation modules, arranged to calculate multiple parity bits according to a set of data bits corresponding to the shorter codeword length, for performing error correction of the set of data bits, wherein any XOR operation module among the multiple XOR operation modules comprises a portion of XOR operation circuits among the first set of XOR operation circuits, for calculating a parity bit among the multiple parity bits according to at least one portion of data bits among the set of data bits.

10. A circuit module that uses the error correction circuit of claim 9, wherein the circuit module comprises the error correction circuit, and the set of data bits represent data bits output or input by the circuit module.
